(19) United States
(12) Patent Application Publication
(10) Pub. No.: US 2005/0078470 A1
(43) Pub. Date: Apr. 14, 2005

(54) Megaphone

(75) Inventor: Tony Yang, Taichung (TW)

Correspondence Address: BACON & THOMAS, PLLC, 625 SLATERS LANE, FOURTH FLOOR, ALEXANDRIA, VA, 22314, US

(73) Assignee: SEKAKU ELECTRON INDUSTRY CO., LTD., TAICHUNG (TW)

(21) Appl. No.: 10/928,161

(22) Filed: Aug. 30, 2004

(30) Foreign Application Priority Data
Oct. 9, 2003 (TW) 92218165

(51) Int. Cl. H05K 5/00; H04M 1/22

(52) U.S. Cl. 362/86

(57) ABSTRACT

A megaphone includes a speaker housing, a centric tube, and an illuminating device. The speaker housing has a mouth portion, a head portion connected to the mouth portion, and a power supply. The centric tube has a tube body, a coupling portion connected to a midsection of the speaker housing, and a lamp mount formed at a front portion of the tube body. The illuminating device is mounted on the lamp mount of the centric tube, having a plurality of light emitting diodes (LEDs) that can be electrically connected with the power supply of the speaker housing to generate illumination.

### BACKGROUND OF THE INVENTION

1. Field of the Invention

The present invention relates generally to megaphones, and more particularly to a megaphone having an illuminating device.

2. Description of the Related Art

A conventional megaphone is generally used for amplifying the voice. However, when the megaphone is used at night or in the dark, an illuminating device is required to work together with the megaphone for illumination, such that it is inconvenient to use the megaphone at night or in the dark.

In addition, when the megaphone is combined with an illuminating device, the illuminating device consumes lots of electricity to cause an impermanent period of illumination and the megaphone consumes certain electricity, such that the illuminating device of the combination has to be energy-saving and generate sufficient illumination to be acceptable and practicable for consumers.

### SUMMARY OF THE INVENTION

The primary objective of the present invention is to provide a megaphone having an illuminating device; the megaphone can be illuminable in addition to voice-amplification to get rid of inconvenience of using an additional illuminating apparatus.

The other objective of the present invention is to provide a megaphone having an illuminating device; the megaphone generates efficient and effective illumination.

Another objective of the present invention is to provide a megaphone having an illuminating device; the megaphone is best combined with the illuminating device to be easily and rapidly knockdown.

The foregoing objectives of the present invention are attained by the megaphone that is composed of a speaker housing, a centric tube, and an illuminating device. The speaker housing has a mouth portion, a head portion connected to the mouth portion, and a power supply. The centric tube has a tube body, a coupling portion connected to a midsection of the speaker housing, and a lamp mount formed at a front portion of the tube body. The illuminating device is mounted on the lamp mount of the centric tube, having a plurality of light emitting diodes (LEDs) that can be electrically connected with the power supply of the speaker housing to generate illumination.

### BRIEF DESCRIPTION OF THE DRAWINGS

FIG. 1 is a side view of a first preferred embodiment of the present invention;

FIG. 2 is an exploded view of the first preferred embodiment of the present invention;

FIG. 3 is a partially exploded sectional view of the first preferred embodiment of the present invention;

FIG. 4 is a sectional view of the first preferred embodiment of the present invention in assembly; and

FIG. 5 is an exploded view of a second preferred embodiment of the present invention.

### DETAILED DESCRIPTION OF THE INVENTION

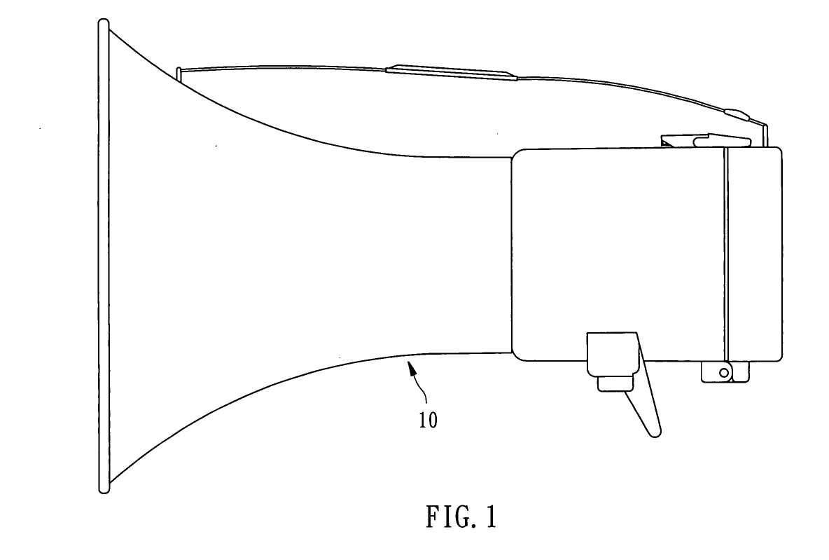

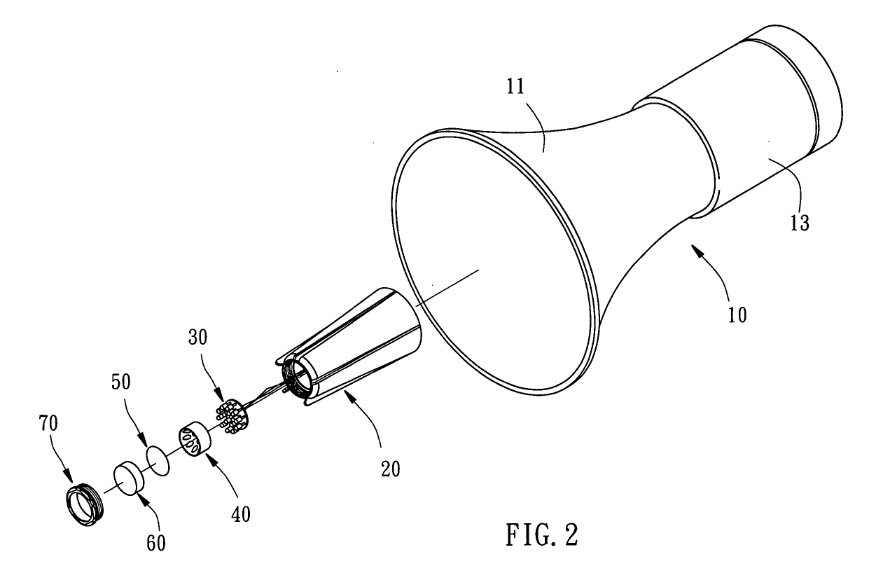

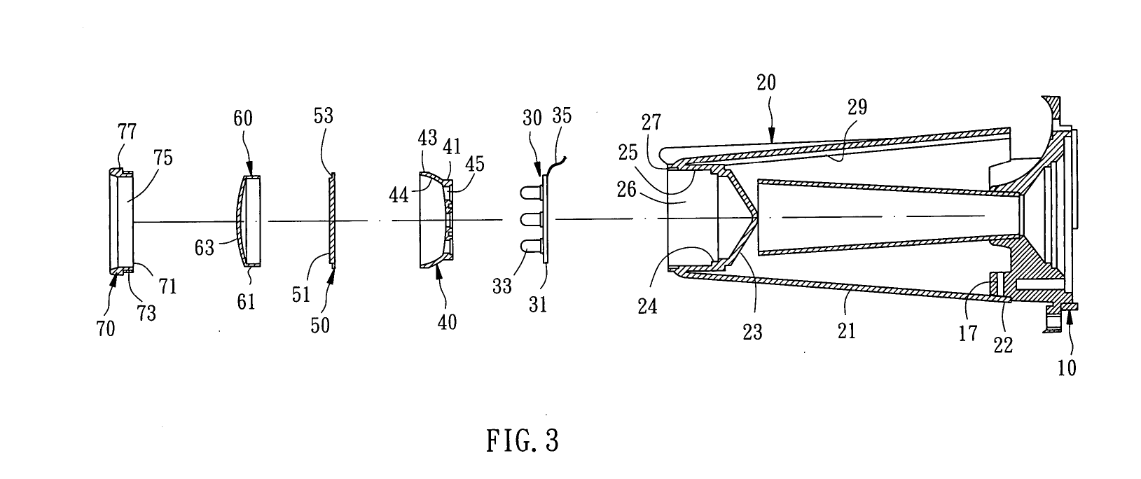

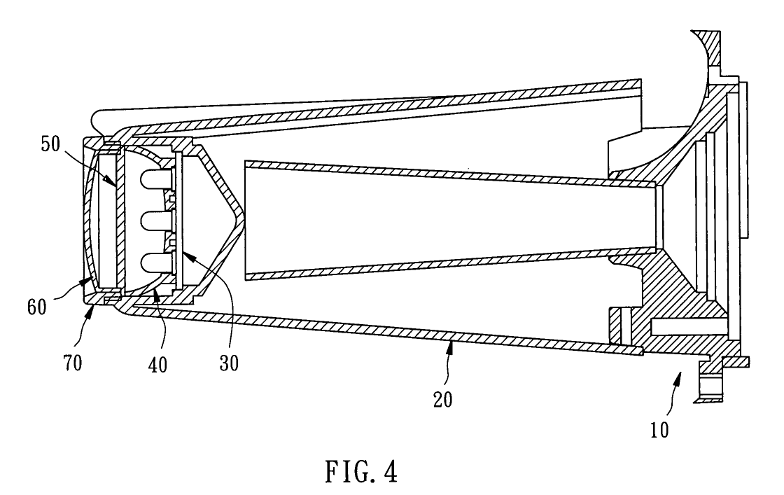

Referring to FIGS. 1-4, a megaphone constructed according to a first preferred embodiment of the present invention is composed of a speaker housing 10, a centric tube 20, an illuminating device 30, a reflector 40, a light filter 50, a shield 60, and a fixing member 70.

The speaker housing 10 has a trumpet-like mouth portion 11, a head portion 13 connected to a rear end of the mouth portion 11, a jointing portion 17 formed at a bottom side inside the mouth portion 11, and a power supply (not shown). The speaker housing 10 is provided to receiving various kinds of necessary parts and components inside which are well-known arts and not to be recited thereafter.

The centric tube 20 has a tube body 21, a coupling portion 22 connected to the jointing portion 17 of the speaker housing 10, a conic closing portion 23 being recessed rearwards and connected to a front end of the tube body 21, a lamp mount 24 formed at a front end of the closing portion 23, a side wall 25, a reception space 26 formed at a center thereof, a fastening portion 27 embodied as an inner threaded hole formed at an inner side of a front end thereof, and an internal channel 29 formed at an inner periphery of the tube body 21.

The illuminating device 30 has a base plate 31 and a plurality of LEDs 33 (light emitting diodes) mounted on the base plate 31 and electrically connected with the power supply of the megaphone via a plurality of wires 35 which running through the internal channel 29 of the centric tube 20.

The reflector 40 has a base member 41 connected to the base plate 31 of the illuminating device 30, a reflecting sleeve 43 connected to the base member 41 to be plugged to the side wall 25 of the centric tube 20, a bowl-like reflecting surface 44 formed at an inner side thereof, and a plurality of through holes 45 formed on the base member 41 for the LEDs 33 of the illuminating device 30 inserting through.

The light filter 50 has a circular sheety member 51 mounted into the reception space 26 of the centric tube 20, and a stepped portion 53 formed at an outer edge of the sheety member 51 and contacting against the side wall 25 of the centric tube 20 and an outer edge of the reflecting sleeve 43 of the reflector 40. In addition, the light filter 50 can be transparent, translucent, of various colors, or of a predetermined design.

The shield 60 is made of glass or acrylic, having an external ring 61 mounted into the reception space 26 of the centric tube 20 and lying against the stepped portion 53 of the light filter 50 at its bottom edge thereof, and a convex lid 63 connected to the external ring 61 and being transparent for the penetration of light.

The fixing member 70 has a body portion 71, a fixing portion 73 having an outer thread formed at an outer side of an end of the body portion 71 for being threaded into the fastening portion 27 of the centric tube 20, a receiving hole 75 axially running therethrough and fitted onto the external ring 61 of the shield 60, and a gripping portion 77 connected to the body portion 71 to be operated by hands or tools to rotate.

The megaphone of the first preferred embodiment of the present invention is assembled according to the following steps. First, install the centric tube 20 to the speaker housing 10. Next, install the illuminating device 30 to the lamp mount 24 of the centric tube 20, and then install the reflector 40, the light filter 50, and the shield 60 in turn to the centric tube 20. Finally, install the fixing member 70 by threading the fixing portion 73 into the fastening portion 27 of the centric tube 20, thereby completing the assembly.

The megaphone of the present invention can function like an illuminating apparatus, such that it's very convenient for the user because the user does not have to carry an additional illuminating apparatus like flashlight.

When the LEDs 33 of the illuminating device 30 are activated to generate light of illumination, part of the light projects forwards and the other part of the light projects onto the reflecting surface 44 of the reflector 40 to be reflected forwards, such that the light entirely projects outwards to cause preferable illuminating effect and brightness.

Alternatively, the light filter 50 can be conveniently changed to other colors to generate the distinguishable light of different colors. In addition, the fixing member 70 and the centric tube 20 are well detachably designed to be securely assembled and conveniently disassembled, and the shield 60 protects the components inside.

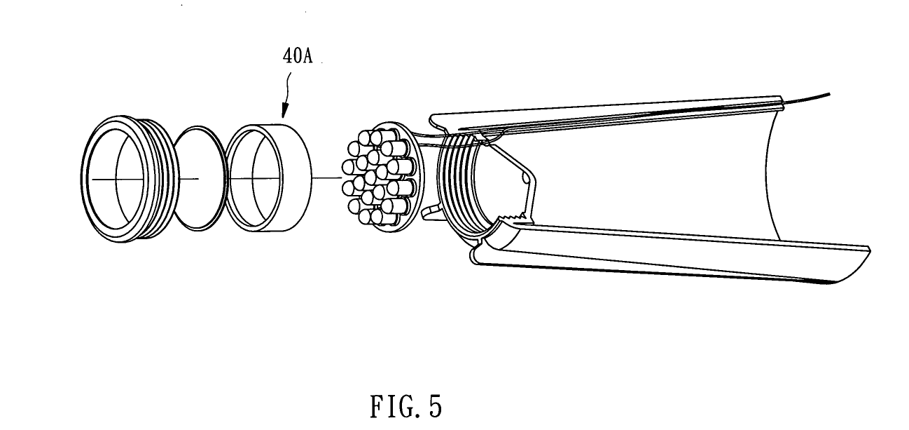

FIG. 5 shows a megaphone constructed according to a second preferred embodiment of the present invention. It is different from the first preferred embodiment by that the megaphone does not comprising the reflector and the shield but further comprising a partition ring 40A mounted between the illuminating device and the light filter.

Further, the LEDs of the illuminating device can alternatively be annularly arranged (not shown) and mounted at an inner edge or an outer edge of the centric tube. Alternatively, the centric tube is integrally formed (not shown) with the speaker housing to simplify the structure and further reduce the cost. Still preferably, the reflector has a plurality of reflecting surfaces (not shown) each corresponding to each of the LEDs, such that the light generated by each of the LEDs can be maximally reflected to cause best illuminating efficiency.

In conclusion, the present invention has three advantages as follows.

1. The present invention can be illuminable in addition to voice-amplification to get rid of inconvenience of using an additional illuminating apparatus.

2. The present invention generates energy-saving, preferably bright and efficient illumination.

3. The present invention includes a best arranged combination of the megaphone and the illuminating device to be easily and rapidly knockdown.

1. A megaphone comprising:
a speaker housing having a mouth portion, a head portion connected to said mouth portion, and a power supply;
a centric tube having a tube body, a coupling portion connected to a midsection of said speaker housing, and a lamp mount formed at a front portion of said tube body; and
an illuminating device mounted to said lamp mount of said centric tube and having a plurality of light emitting diodes (LEDs) electrically connected with said power supply of said speaker housing for generating illumination.

2. The megaphone as defined in claim 1, further comprising a reflector for reflecting the light generated by said LEDs of said illuminating device.

3. The megaphone as defined in claim 2, wherein said reflector has a plurality of through holes for said LEDs inserting through.

4. The megaphone as defined in claim 1, further comprising a light filter for the light of the illumination generated by said LEDs of said illuminating device penetrating through to project outwards.

5. The megaphone as defined in claim 1, further comprising a fixing member for fixedly securing said illuminating device to said centric tube.

6. The megaphone as defined in claim 5, wherein said fixing member has a fixing portion; said centric tube has a fastening portion for being threaded with said fixing portion of said fixing member.

7. The megaphone as defined in claim 1, further comprising a shield mounted in front of said illuminating device.

8. The megaphone as defined in claim 1, wherein said centric tube further has a closing portion.

9. The megaphone as defined in claim 1, wherein said centric tube is integrally formed with said speaker housing.

10. The megaphone as defined in claim 1, wherein said illuminating device further has a base plate; said LEDs are mounted on said base plate.
